(19) United States
(12) Patent Application Publication
(10) Pub. No.: US 2006/0008595 A1
(43) Pub. Date: Jan. 12, 2006

(54) Film-forming method

(75) Inventors: Tadahiro Ishizaka, Albany, NY (US); Atsushi Gomi, Albany, NY (US); Tatsuo Hatano, Nirasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/174,532

(22) Filed: Jul. 6, 2005

(30) Foreign Application Priority Data
Jul. 6, 2004 (JP) 2004-199678

(51) Int. Cl. H05H 1/24; C23C 16/00

(52) U.S. Cl. 427/569; 427/248.1

(57) ABSTRACT

A plurality of gases are prevented from being mixed with each other in a gas supply path when forming a film on a substrate to be processed so as to prevent generation of particles to enable a stable and clean film formation. A film containing metal is formed on a substrate to be processed by supplying a first process gas containing the metal and a second process gas for reducing the first process gas to a process chamber. The first process gas is supplied from a first gas supply passage to the process chamber. The second process gas is supplied from a second gas supply passage to the process chamber and the second process gas is plasma-excited in the process chamber. A first reverse flow preventing gas consisting of H₂ or He is supplied to the process chamber from the first gas supply passage when supplying the second process gas.

### BACKGROUND OF THE INVENTION

1. Field of the Invention

The present invention relates to a film-forming method of forming a film containing metal on a substrate to be processed.

2. Description of the Related Art

In recent years, with high-performance of semiconductor devices, a high integration of a semiconductor device progresses, and the demand for miniaturization becomes remarkable. The wiring rule is developed into an area of 0.10 μm or less. As for a thin film used for forming such a high-performance semiconductor device, a high-quality film is required, such as less impurity in the film and good crystal orientation. Further, it is required to have good coverage when forming a micro-pattern.

As for a film-forming method satisfying the above-mentioned requirements, there is suggested a method of obtaining a thin film having a predetermined thickness by forming the film with a level close to an atomic layer or a molecular layer according to adsorption of a plurality of kinds of process gases onto a reaction surface while supplying the process gases alternately on an individual kind basis when forming the film and repeating those processes. Such a film-forming method may be referred to as an Atomic Layer Deposition method (ALD method).

An outline of such a film-forming method according to the ALD method is explained below. First, a process chamber is prepared that has a first gas supply path for supplying a first gas and a second gas supply path for supplying a second gas. The first and the second gases are supplied alternately into the process chamber. Specifically, the first gas is supplied first onto a substrate in the process chamber so as to form an adsorption layer on the substrate. Thereafter, the second gas is supplied onto the substrate so as to react with the first gas. This process is repeated for a predetermined times as needed. According to this method, since the first gas react with the second gas after it is adsorbed onto the substrate, a film-forming temperature can be reduced. Additionally, a high-quality film having less impurity can be obtained. In forming a micro pattern there is no void being formed due to reaction and consumption of a process gas on an upper portion of a hole, which is a problem in a conventional CVD method, thereby providing a good coverage characteristic.

According to the above-mentioned film-forming method, a film containing a metal can be formed using a gas containing the metal as the first gas and a reducing gas reducing the first gas as the second gas. For example, a film of Ta, Tan, Ti, TiN, W, WN, etc., can be formed.

In a case of forming TiN film as an example, the TiN film can be formed using a compound, such as TiCl₄, containing Ti as the above-mentioned first process gas and a reducing gas containing nitrogen such as plasma-excited NH₃ as the above-mentioned second process gas. In such a case, the reason for using the plasma-excited NH₃ is to reduce in-film impurity concentration of the TiN film formed.

Since the film formed by the above-mentioned film-forming method has a high-quality and is excellent in a coverage characteristic, there is a case in which the film is used for a Cu diffusion preventing film, which is formed between an insulating film and a copper layer in formation of Cu wiring in a semiconductor device.

However, when the film-forming method of forming a film by supplying a plurality of gases into a process chamber, there may be a case in which the plurality of gases area mixed in an area other than the reaction surface of the substrate to be processed, which produces generation sources of particles. For example, when performing an atomic level or a molecular level film formation by supplying alternately the above-mentioned first and second gases, the gases supplied into the process chamber may diffuse or enter into a gas supply path of gases other than the gas concerned, which causes a problem in that the gases are mixed and react with each other.

For example, there is a case in which, when supplying the second gas into the process chamber through the second gas supply path, the second gas enters the first gas supply path, which results in the first gas and the second gas being react with each other and a particle generation source is produced.

Additionally, if a method of supplying a reverse-flow preventing gas such as Ar is used as means for preventing such a mixture of gases, there is a problem in that the reverse prevention gives influences to the film formation. For example, when plasma excitation is performed in a film-forming process, the reverse-flow preventing gas may be plasma-excited, which results in generation of ions due to ionization of the reverse-flow preventing gas. The ions may generate sputtering of a wall surface of the process chamber, and there is a problem in that particles and impurities scatter in the process chamber.

### SUMMARY OF THE INVENTION

It is a general object of the present invention to provide an improved and useful film-forming method in which the above-mentioned problems are eliminated.

More specific object of the present invention is to provide a film-forming method which can prevent a plurality of gases from being mixed with each other in a gas supply path when forming a film on a substrate to be processed using the plurality of gases so as to prevent generation of particles to enable a stable and clean film formation.

In order to achieve the above-mentioned objects, there is provided according to the present invention a film-forming method of forming a film containing metal on a substrate to be processed by supplying a first process gas containing the metal and a second process gas for reducing the first process gas to a process chamber, comprising: a first step of supplying the first process gas from a first gas supply passage to the process chamber; and a second step of supplying the second process gas from a second gas supply passage to the process chamber and exciting plasma of the second process gas by plasma exciting means provided to the process chamber, wherein, in the second step, a first reverse flow preventing gas consisting of H₂ or He is supplied to the process chamber from the first gas supply passage.

In the film-forming method according to the present invention, the first step and the second step may be repeated alternately for a plurality of times.

The film-forming method according to the present invention may further comprise a step of purging the process chamber after each of the first step and the second step.

In the film-forming method according to the present invention, in the first step, a second reverse flow preventing gas may be supplied to the process chamber from the second gas supply passage. The second process gas and the first reverse flow preventing gas may be the same kind of gas. The second process gas may be H₂. The first reverse flow preventing gas may be H₂. The second reverse flow preventing gas may be Ar.

In the film-forming method according to the present invention, the metal may be one of Ta, Ti and W.

In the film-forming method according to the present invention, the first process gas may be one of an amide compound gas, a halogen compound gas and a carbonyl compound gas. The amide compound gas may be a gas selected from a group consisting of Ta(NC(CH₃)₂(C₂H₅)(N(CH₃)₂)₃, Ta[N(C₂H₅CH₃)] ₅, Ta[N(CH₃)₂]₅, Ta(NC(CH₃)₃(N(C₂H₅)₂)₃, Ta(NC(CH₃)₃(N(CH₃)₂)₃, Ta(NC₂H₅)(N(C₂H₅)₂)₃, Ta(N(C₂H₅)₂(N(C₂H₅)₂)₃, Ti[N(C₂H₅CH₃)]₄, Ti[N(CH₃)₂]₄ and Ti[N(C₂H₅)₂]₄. The halogen compound gas may be a gas selected from a group consisting of TaF₅, TaBr₅, TaI₅, TiCl₄, TiF₄, TiBr₄, TiI₄ and WF₆. The carbonyl compound gas may be W(CO)₆.

In the film-forming method according to the present invention, the first process gas and the second process gas may be supplied to the process chamber through a shower head part provided in the process chamber. The plasma exciting means may include the shower head part to which a high-frequency power is applied to excite plasma.

According to the present invention, when forming a film on a substrate to be processed using a plurality of gases, the plurality of gases are prevented from being mixed with each other in a gas supply passage, which suppresses generation of particles in the gas supply passage and provides a stable and clean film formation.

Other objects, features and advantages of the present invention will become more apparent from the following detailed description when read in conjunction with the accompanying drawings.

### BRIEF DESCRIPTION OF THE DRAWINGS

FIG. 1 is an illustration showing a film-forming apparatus that performs a film-forming method according to a first embodiment of the present invention;

FIG. 2 is an illustrative cross-sectional view of a shower head part shown in FIG. 1;

FIG. 3 is a flowchart of an example of the film-forming method according to the first embodiment of the present invention; and

FIGS. 4A through 4D are graphs showing result of analysis on films formed by the film-forming method according to the first embodiment of the present invention.

### DETAILED DESCRIPTION OF THE PREFERRED EMBODIMENTS

A description will now be given of a film-forming method according to a first embodiment of the present invention.

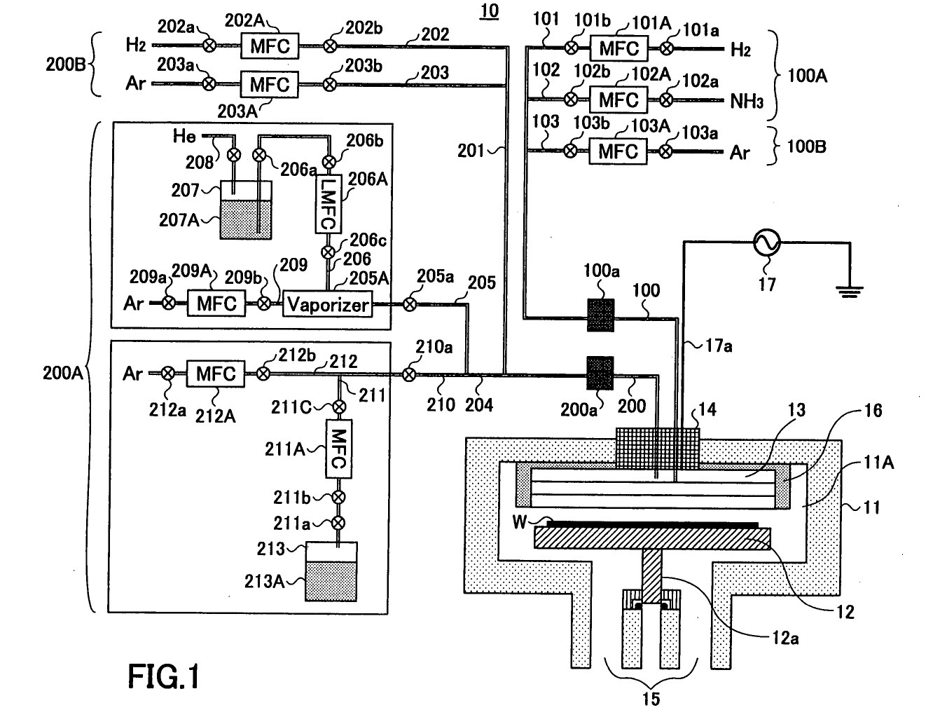

FIG. 1 is an illustration of a film-forming apparatus which performs the film-forming method according to the first embodiment of the present invention.

The film-forming apparatus shown in FIG. 1 comprises a process chamber 11, which can accommodate an object W to be processed therein. A first process gas and a second process gas is supplied into a process space 11A formed inside the process chamber 11 through a gas line 200 and a gas line 100, respectively.

The process gases are supplied to the process space 11A alternately on an individual kind basis so as to form a film at a level close to an atomic layer or a molecular layer through adsorption of the process gases onto a surface of the object W to be processed. Such a process is repeated so as to form a film having a predetermined thickness on the object W to be processed. This film-forming method is generally referred to as the Atomic Layer Deposition (ALD) method. The film formed by the ALD method has less impurities and high-quality even though a film-forming temperature is low. Additionally, the ALD method provides a good coverage when forming a micro pattern.

According to the film-forming method according to the present embodiment, a reverse-flow preventing gas is supplied to the process space 11A through the gas line 200 or the gas line 100 during film formation, which prevents the first gas and the second gas from being mixed with each other in the gas supply path. Thereby, generation of particles is suppressed and a clean and stabel film can be formed. A specific method of supplying a reverse flow preventing gas will be mentioned later.

A description will be given of the film-forming apparatus in detail. The film-forming apparatus 10 shown in FIG. 1 has the process chamber 11, which is made of, for example, aluminum, aluminum with an anodized surface, or stainless steal. A substrate support table 12 is located inside the process chamber 11 by being supported by a substrate support table support part 12a. The substrate support table 12 has a generally circular shape and is made of, for example, hastelloy. A semiconductor substrate W to be processed is placed on the substrate support table 12. A heater (not shown in the figure) is incorporated in the substrate support table 12 so as to heat the substrate W to be processed.

The process space 11A inside the process chamber 11 is subjected to evacuation by evacuating means (not shown in the figure) connected to an exhaust port 15 so that the process area 11A is set in a depressurized state. Additionally, the substrate W to be processed is carried in or taken out of the process chamber 11 through a gate valve (not shown in the figure) provided to the process chamber.

Moreover, a generally cylindrical shower head part 13 made of, for example, aluminum is located so as to face the substrate support table 12 in the process chamber 11. An insulator 6 made of, for example, quartz, SiN, AlN, etc., is provided to the sidewall surface of the shower head part 13 and between the shower head part 13 and an upper wall of the process chamber 11.

Moreover, an opening is provided in the upper wall of the process chamber 11 above the shower head part 13, and an insulator 14 made of an insulating material is inserted into the opening. A conductor line 17a connected to a high-frequency power supply 17 is inserted into the insulator 14. The conductor line 17a is connected to the shower head part 13 so that a high-frequency power is applied to the shower head part 13 through the conductor line 17a.

Moreover, the gas line 200, which supplies the first process gas to the process space 11A, and the gas line 100, which supplies the second process gas to the process space 11A, are connected to the shower head part 13 so that the first and second process gases are supplied to the process space 11A through the shower head part 13. Moreover, insulators 200a and 100a are inserted into the gas lines 200 and 100, respectively, so that the gas lines area isolated from the high-frequency power.

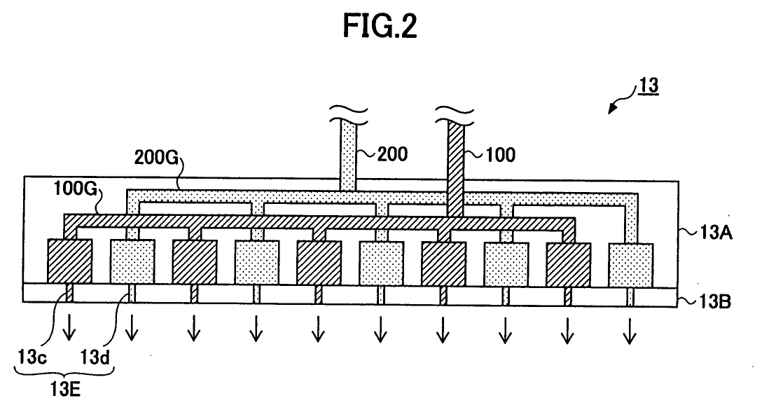

FIG. 2 is an illustrative cross-sectional view of the shower head part 13. In FIG. 2, parts that are the same as the parts shown in FIG. 1 are given the same reference numerals, and descriptions thereof will be omitted. The shower head part 13 comprises a shower head body 13A and a shower plate 13B attached to the shower head body 13A. The shower had body 13A includes a gas flow passage 200G for the first process gas and a gas flow passage 100G for the second process gas. Formed in the shower plate 13B are a plurality of gas holes 13E including gas holes 13c and 13d.

The gas flow passage 200G connected to the gas line 200 is further connected to the gas holes 13d of the shower plate 13B. Accordingly, the first process gas is supplied to the process space 11A through the first gas supply path, which comprises the gas line 200, the gas flow passage 200G and the gas holes 13d. On the other hand, the gas flow passage 100G connected to the gas line 100 is further connected to the gas holes 13c of the shower plate 13B. Accordingly, the first process gas is supplied to the process space 11A through the second gas supply path, which comprises the gas line 100, the gas flow passage 100G and the gas holes 13c.

Thus, the passages of the first process gas and the second process gas are formed independently in the shower head part 13, and the first process gas and the second process gas are mixed with each other in the process space 11A. That is, the shower head part 13 forms a so-called post-mix type shower head.

Moreover, a first process gas supply part 200A, which supplies the first process gas to the gas line 200, is connected to the gas line 200 via a gas line 204. Additionally, a reverse flow preventing gas supply part 200B, which supplies a reverse flow preventing gas to the gas line 200, is connected to the gas line 200 via a gas line 201.

Similarly, a second first process gas supply part 10A, which supplies the second process gas to the gas line 100, and a reverse flow preventing gas supply part 100B, which supplies a reverse flow preventing gas to the gas line 100, are connected to the gas line 100.

First, a description will be given of the first process gas supply part 200A. The gas line 204 is connected with a gas line 205 provided with a valve 205a and a gas line 210 provided with a valve 210a. That is, the gas line 204 has a structure in which the two kinds of process gases, which are supplied through the gas line 205 and the gas line 210, are used by switching by opening and closing of the valves.

A vaporizer 205A, which evaporates a liquid material, is connected to the gas line 205 through the valve 205a. The vaporizer 205A vaporizes the liquid material supplied from a line 206 so as to change into the first process gas, and supplies the thus produced first process gas to the gas line 200 through the gas line 204 together with a carrier gas, such as, for example, Ar or the like, supplied from a line 209.

The line 206 supplying the liquid material to the vaporizer 205A has a liquid mass-flow controller 206A and valves 206a, 206b ad 206c, and is connected to a material container 207 storing a material 207A therein. a material containing metal such as, for example, Ta(NC(CH₃)₂C₂H₅)(N(CH₃)₂)₃, is stored in the material container 207A. The material is pressurized by a gas such as, for example, He or the like, supplied through a gas line 208 so as to be supplied to the vaporizer 205A.

Moreover, the gas line 210 is connected with a mass-flow controller 211A, and a line 211 provided with valves 211a, 211b and 211s. The line 211 is connected to material container 213, which stores a material 213A such as, for example, TaCl₅ or the like. Additionally, the gas line 210 is connected with a mass-flow controller 212A and a gas line 212, which is provided with valves 212a and 212b and introduces a carrier gas such as, for example, Ar or the like. The first process gas is supplied to the process space 11A together with a carrier gas such as Ar or the like from the gas line through the gas line 200 and further the shower head part 13.

Moreover, the reverse flow preventing gas supply part 200B includes a gas line 202 connected to a H₂ gas supply source and a gas line 203 connected to an Ar gas supply source. The gas line 202 is provided with a mass-flow controller 202A and valves 202a and 202b and the gas line 203 is provided with a mass-flow controller 203A and valves 203a and 203b so that the reverse flow preventing gas can be selected and a flow of the reverse flow preventing gas can be controlled.

On the other hand, the second process gas supply part 100A connected to the gas line 100 comprises a gas line connected with a H₂ gas supply source and a gas line connected with a NH3 gas supply source. The gas line 101 is connected with a mass-flow controller 102A and valves 102a and 102b so that the second process gas supplied to the gas line 100 is selected and a flow of the second process gas is controlled.

Moreover, the reverse flow preventing gas supply part 100B connected to the gas line 100 comprises a mass-flow controller 103A connected with an Ar gas supply source and a gas line 103 provided with a mass-flow controller 103A and valves 103a and 103b so that a flow of the reverse flow preventing gas supplied to the gas line 100 is controlled.

When forming a film containing metal on the substrate W to be processed placed on the substrate support table 12 using the above-mentioned film-forming apparatus 10, the film-forming apparatus is controlled as follows.

First, the first process gas containing metal is supplied from the first process gas supply part 200A to the process space 11A through the gas line 200 and the shower head part 13. After the first process gas is adsorbed onto the substrate to be processed, the first process gas remaining in the process space is evacuated through the exhaust port 15. In this case, the process space 11A may be purged by a purge gas.

Then, the second process gas, which reduces the first gas, is supplied to the process space 11A from the second process gas supply part 101A through the gas line 100 and the shower head part 13. Additionally, in this case, it is preferable to apply a high-frequency to the shower head part 13 by the high-frequency power supply 17 so as to excite plasma of the second process gas in the process space 11A, which progresses dissociation of the second process gas and promotes the reduction of the first process gas.

Then, the second process gas remaining in the process space 11A is evacuated through the exhaust port 15. In this case, the process space 11A may be purged using a purge gas.

Repeating the above-mentioned process to supply the first process gas to the process space and evacuate the first gas and further supply the second gas to the process space and evacuate the second gas, a film containing metal and having a predetermined thickness, a film containing metal nitride or the like can be formed on the substrate W to be processed.

The film formed by the ALD method has few impurities therein, and has an advantage of a good film quality.

However, conventionally, there is a problem in that the first process gas and the second process gas, that is, the gas containing metal and a reducing gas, are mixed with each other in a space other than the process space 11A, which produces a generation source of particles. Such particles may cause deterioration of a yield rate in a semiconductor manufacturing process using the film-forming process.

For example, in the process of supplying the first process gas to the process space 11A, the first process gas supplied to the process space 11A may diffuse or enter the second gas supply passage for supplying the second process gas, such as the gas holes 13d, the gas flow passage 100G and the gal line 100. Thereby, the first process gas and the second process gas react with each other in the second process gas supply passage, which causes generation of particles. Similarly, in the process of supplying the second process gas to the process space 11A, the second process gas supplied to the process space 11A may diffuse or enter the first gas supply passage for supplying the first process gas, such as the gas holes 13c, the gas flow passage 200G and the gal line 200 shown in FIG. 2. Thereby, the first process gas and the second process gas react with each other in the first process gas supply passage, which causes generation of particles.

Thus, in the film-forming method according to the present invention, the reverse flow preventing gas is supplied to the process space 11A through the second supply passage in the process of supplying the first process gas to the process space 11A, and the reverse flow preventing gas is supplied to the process space 11A through the first supply passage in the process of supplying the second process gas to the process space 11A. Accordingly, the second process gas is prevented from being diffused or entering into the first supply passage and generation of particles due to reaction of the first process gas and the second process gas in the first gas supply passage can be suppressed. Similarly, the first process gas is prevented from being diffused or entering into the second supply passage and generation of particles due to reaction of the first process gas and the second process gas in the second gas supply passage can be suppressed.

Moreover, especially when the second process gas is supplied to the process space 11A and plasma excitation is performed, it is possible that a problem occurs in the film-forming process depending on a kind of the reverse flow preventing gas. For example, there is a problem in that, when a gas having a relatively large mass (large atomic number) such as Ar or the like is uses as the reverse flow preventing gas, ions generated by ionization of the reverse flow preventing gas generate sputtering of the shower head part 13 and the inner wall of the process camber 11 in the process space 11A, which causes scatter of particles or pollution sources. For example, the material, such as Al or other metals, forming the inner wall of the shower head part 13 and the process chamber 11 are sputtered and incorporated into the film on the substrate to be processed, which produces pollution sources.

Thus, in the present embodiment, when the second process gas is supplied, a gas having a small mass (small atomic number) such as, for example, H₂ gas, is uses as the reverse flow preventing gas supplied from the first gas supply passage so as to reduce an amount of sputtering portion of the shower head part, which suppresses scattering of particles and pollution substances and consequently suppressing mixture of impurities in the film. The reverse flow preventing gas is not limited to H2, and it is possible to use other gas having a small mass such as, for example, He gas.

Furthermore, it is further preferable if the reverse flow preventing gas supplied from the first gas supply passage is the same as the second process gas supplied from the second gas supply passage. In such a case, if H₂ gas is uses as the second process gas, that is, the reducing gas which reduces the first process gas, it is preferable to use H₂ gas as the reverse flow preventing gas supplied from the first gas supply passage.

In this case, substantially only H₂ gas is supplied to the process space 11A from the first gas supply passage and the second gas supply passage. Thus, there is no impurity entering into the film from the reverse flow preventing gas. Further, an amount of sputtering of the shower head part is reduced, which reduces an amount of scattering pollution substances. Thus, an amount of pollution substances taken into the film is reduced, which results in a good quality of the film formed.

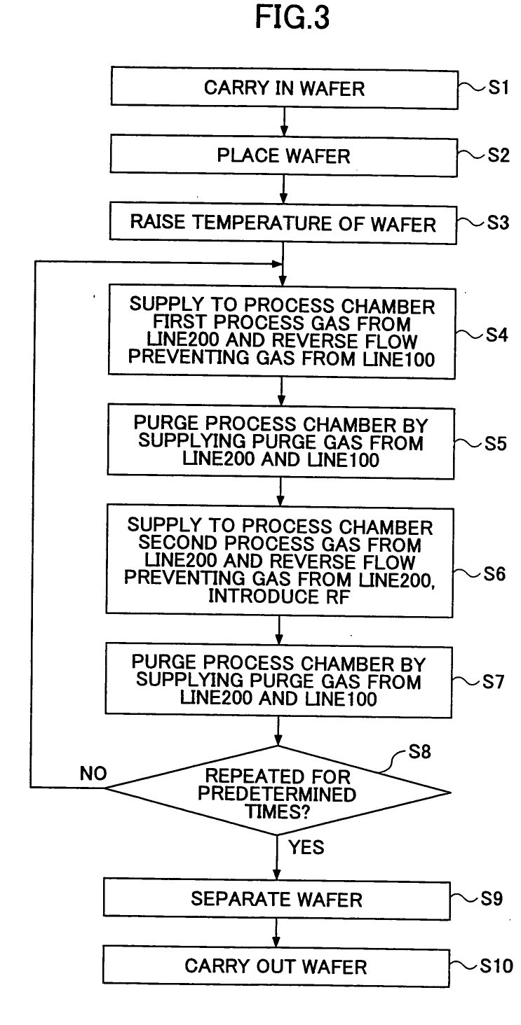

A description will now be given, with reference to a flowchart shown in FIG. 3, of an example of film formation using the film-forming apparatus 10.

FIG. 3 is a flowchart showing a film-forming method according to the present embodiment.

First, the substrate W to be processed is carried into the film-forming apparatus 10 in step S1.

Then, in step S2, the substrate W to be processed is placed on the substrate support table 12.

In step S3, the temperature of the substrate W is raised by the heater incorporated in the substrate support table 12.

Then, in step S4, the valves 206a, 206b and 206c are opened so as to supply the liquid material 207A, which is a liquid of Ta (NC(CH₃)₂C₂H₅)(N(CH₃)₂)₃, from the material container 66 to the vaporizer 205A through the line 206 while controlling a flow of the liquid material 207A by the liquid mass-flow controller 206A.

In the vaporizer 205A, the first gas is produced by vaporizing the liquid material 207A. The first process gas is supplied to the process space 11A through the gas line 205, the gas line 204 and the gas line 200 together with Ar, which is also supplied to the vaporizer 205A through the gas line 209.

In this step, the first process gas is supplied onto the substrate W to be processed, which results in adsorption of the first process gas onto the substrate W.

Additionally, in this step, the valve 103a and the valve 103b are opened so as to supply Ar gas, which serves as the reverse flow preventing gas, to the process space 11A through the gas line 100 while controlling a flow of the reverse flow preventing gas. Thus, it can be suppressed that the first process gas diffuses or enters into the second gas supply passage and the first process gas and the second process gas react with each other in the second gas supply passage, which causes generation of particles.

Then, in step S5, the valves 206a, 206b and 206c are closed to stop the supply of the first process gas to the process space 11A so as to discharge the first process gas, which is not adsorbed onto the substrate W and remaining in the process space 11A, out of the process chamber 11 through the exhaust port 15. In this case, the valves 203a and 203b and the valves 103a and 103b are opened so as to purge the process space 11A by introducing Ar gas as a purge gas through the gas line 200 and the gas line 100. In this case, the remaining first process gas can be rapidly discharged from the process space 11A. After the purge of a predetermined period is completed, the valves 203a and 203b and the valves 103a and 103b are closed.

Then, in step S6, the valves 101a and 101b are opened so as to introduce H2 gas into the process space 11A through the gas line 100 while controlling a flow of the H2 gas by the mass-flow controller 101A. Additionally, a high-frequency or radio-frequency power (RF) is applied from the high-frequency power supply 17 to the shower head part 13 so as to perform plasma excitation in the process space 11A. In this case, H₂ gas in the process space 11A is dissociated and changed into H+/H* (hydrogen ions and hydrogen radials). Then, the first process gas (Ta₃ (NC(CH₃)₂C₂H₅)(N(CH₃)₂)) reacts with H+/H*, thereby producing Ta(C)N. In this case, the second process gas may be supplied for a predetermined time period so as to stabilize the flow of the second gas and to increase the pressure in the process space 11A.

In this step, the valve 202a and the valve 202b are opened so as to supply the H₂ gas, which serves as the reverse flow preventing gas, to the process space 11A through the gas line 200 while controlling a flow of the Hs gas by the mass-flow controller 202A. Accordingly, it can be suppressed that the second process gas diffuses or enters into the first gas supply passage and the first process gas and the second process gas react with each other in the first gas supply passage, which causes generation of particles.

Moreover, in this case, since the reverse flow preventing gas supplied from the first gas supply passage is the same as the second process gas supplied from the second gas supply passage, substantially only H₂ gas is supplied from the first gas supply passage and the second gas supply passage. Thus, there is no impurity entering the film from the reverse flow preventing gas during the film-forming process. Additionally, the excited plasma is stabilized. Further, since the reverse flow preventing gas is the H₂ gas having a small mass, an amount of sputtering of the shower head part is reduced, which reduces an amount of scattered pollution substances. Thereby, an amount of pollution substances taken into the film is reduced, which achieves formation of a good quality film.

Then, in step S7, the valves 206a, 206b and 206c are closed to stop the supply of the second process gas to the process space 11A so as to discharge the second process has, which is not reacted with the first process gas on the substrate W and remaining in the process space 11A, out of the process chamber through the exhaust port 15. In this case, the valves 203a and 203b and the valves 103a and 103b are opened so as to purge the process space by introducing Ar gas as a purge gas from the gas line 2000 and gas line 100. In this case, the second process gas can be rapidly discharged from the process space 11A. After the purge of a predetermined time period is completed, the valves 101a and 101b and the valves 202a and 202b are closed.

Then, in step S8, it is determined whether or not the process of step S4 through step S7 has been repeated for a predetermined number of timed. If not, the routine returns to step S4 so as to repeat the process for the predetermined time. If the process has been repeated for the predetermined time so as to form a film having a desired thickness, the routine proceeds to step S9.

Then, in step S9, the substrate W to be processed is separated from the substrate support table 12. In step S10, the substrate W is carried out of the process chamber 11.

As mentioned above, a film containing metal such as, for example, Ta(C)N film is formed on the substrate W by the film-forming method according to the present embodiment. It should be noted that the Ta(C)N film is a film containing at least Ta, C and N therein, and coupling state and content of those elements are not limited and impurities may be contained in the film. Additionally, the content of the elements may be changed by changing film-forming conditions or gases to be used.

Moreover, since the film containing metal formed by the film-forming method according to the present embodiment has less impurities and is a high-quality film and a good coverage characteristic can be achieved when forming a micro pattern, it is suitable to use the film-forming method to form a diffusion preventing film (a barrier film or an adhesion film) of Cu wiring in a high-performance semiconductor device having a micro wiring patter.

Moreover, the film which can be formed by the film-forming method according to the present embodiment is not limited to a film containing Ta, such as Ta(C)N film. That is, a film containing metal such as, for example, Ti, W, etc., may be formed, and an effect the same as the effect of formation of the film containing Ta can be provided.

For example, it is possible to form a Ta film, a TaN film, a Ta(C) N film, a Ti film, a TiN film, a Ti(C) N film, a W film, a WN film, a W(C) N film, etc., by the film-forming method according to the present embodiment. It should be noted that the Ta(C)N film is a film containing at least Ta, C and N therein, and a coupled state and content of each element are not limited. Similarly, the Ti(C)N film and the W(C)N film are films containing at least Ti, C and N and W, C and N, respectively therein, and a coupled state and content of each element are not limited. Additionally, also in a case to forming the TaN film, the TiN film and the WN film, especially in a case where a gas containing C is used as the first process gas, C may remain in the film. Additionally, the composition and the content of each element may be changed as needed.

For example, in the film-forming method shown in FIG. 3, the material 207A may be replaced by the material 213A. That is, the same process can be performed by changing the first process gas from Ta(NC(CH₃)₂C₂H₅) (N(CH₃)₂)₃ to TaCl₅ so that the first process gas is supplied to the shower head part 13 through the gas line 210, the gas line 204 and the gas line 200. In this case, a Ta film is formed on the substrate W to be processed.

Moreover, in the film-forming method shown in FIG. 3, the same process can be performed by changing the second process gas from H₂ gas to NH₃ gas so that the second process gas is supplied to the shower head part 13 through the gas line 102 and the gas line 100. In this case, a film mainly containing Ta and N (TaN film) is formed on the substrate to be processed. In this case, it is not always necessary to use the plasma excited second process gas, and, for example, Ta (NC(CH3)2C2H5) (N(CH3) 2)3 adsorbed onto the substrate to be processed can be reduced by using NH3 which is not plasma-excited.

Moreover, the first process gas is not limited to the above-mentioned example, and other various kinds of process gases may be used. For example, one of an amide compound gas, a halogen compound gas and carbonyl compound gas may be used as the first process gas.

For example, as for the amide compound gas, a gas selected from a group consisting of Ta(NC(CH₃)₂(C₂H₅)(N(CH₃)₂)₃, Ta[N(C₂H₅CH₃)]₅, Ta[N(CH₃)₂]₅, Ta(NC(CH₃)₃(N(C₂H₅)₂)₃, Ta(NC(CH₃)₃(N(CH₃)₂)₃, Ta(NC₂H₅)(N(C₂H₅)₂)₃, Ta(N(C₂H₅)₂(N(C₂H₅)₂)₃, Ti[N(C₂H₅CH₃)]₄, Ti[N(CH₃)₂]₄ and Ti[N(C₂H₅)₂]₄ can be used.

Moreover, for example, as for the halogen compound, a gas selected from a group consisting of TaF₅, TaBr₅, TaI₅, TiCl₄, TiF₄, TiBr₄, TiI₄ and WF₆ can be used.

Further, as for the carbonyl gas, W(CO)₆ can be used.

The above-mentioned compounds for the first process gas may be a solid or a liquid at normal temperature, or may be a gas. If it is a liquid, it is vaporized by heating or vaporized using a vaporizer so a to produce a gas. If it is a solid, it can be sublimated by heating so as to produce a gas. Additionally, a solid material may be dissolved in a solvent and the solvent can be vaporized to produce the first process gas.

For example, although Ta (NC(CH3)2C2H5) (N(CH3) 2)3 explained as an example of the material 207A in the present embodiment is a solid at a normal temperature, it can be treated as a liquid at a normal temperature by dissolving in a solvent containing solution of Hexane. Such a liquid can be vaporized by a vaporizer such as shown in FIG. 1 so as to produce the first process gas. It should be noted that a heater (not shown in the figure) is attached to the material container 207 of the film-forming apparatus 10 shown in FIG. 1 so that a solid material can be liquefied by heating.

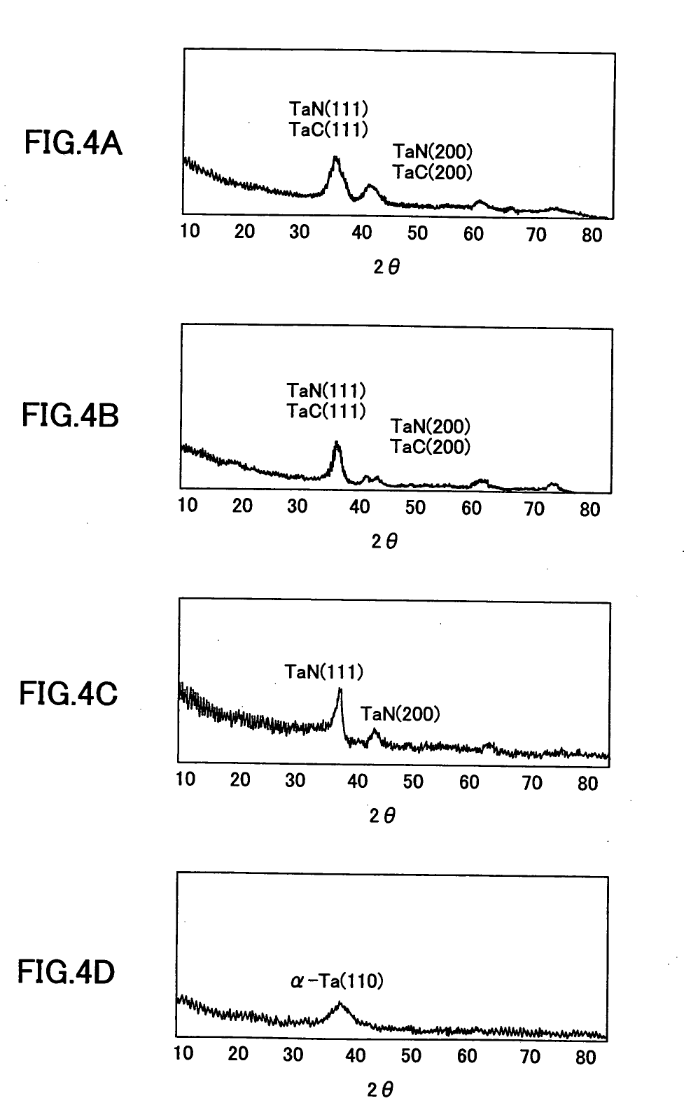

FIGS. 4A through 4D show results of analysis of films formed by the film-forming method shown in FIG. 3 using the film-forming apparatus shown in FIG. 1, the analysis being made by an X-ray diffraction apparatus (XRD). FIG. 4B shows a result of analysis by an XRD in a case where a Ta(C)N film is formed on the substrate to be processed using Ta(NC(CH₃)₂C₂H₅) (N(CH₃)₂)₃ as the first process gas and H2 as the second process gas. FIG. 4B shows a result of analysis by an XRD in a case where the same gases as the case of FIG. 4A are used and 0.1 mol/l solution of Hexane is used as a solvent for dissolving a solid of Ta(NC(CH₃)₂C₂H₅) (N(CH₃)₂)₃. FIG. 4C shows a result of analysis by an XRD in a case where a TaN film is formed on the substrate to be processed using Ta(NC(CH₃)₂C₂H₅) (N(CH₃)₂)₃ as the first process gas and NH₃ as the second process gas. FIG. 4D shows a result of analysis by an XRD in a case where a Ta film is formed on the substrate to be processed using TaCl₅ as the first process gas and H₂ as the second process gas.

Referring to FIGS. 4A through 4D, for example, Ta—N bond and Ta—C bond were observed in the case of FIG. 4A, and the same bonds were observed in the case of FIG. 4B. Additionally, Ta—N bond was observed in the case of FIG. 4C, and α-Ta was observed in the case of FIG. 4D.

Additionally, there was no remarkable impurity or defect observed in the film. Thus, it was confirmed that a good and stable film formation was performed.

According to the present embodiment, when forming a film on a substrate to be processed using a plurality of gases, the plurality of gases are prevented from being mixed with each other in a gas supply passage, which suppresses generation of particles in the gas supply passage and provides a stable and clean film formation.

The present invention is not limited to the specifically disclosed embodiments, and variations and modifications may be made without departing from the scope of the present invention.

The present application is based on Japanese priority application No. 2004-199678 filed Jul. 6, 2004, the entire contents of which are hereby incorporated herein by reference.

What is claimed is:

1. A film-forming method of forming a film containing metal on a substrate to be processed by supplying a first process gas containing the metal and a second process gas for reducing the first process gas to a process chamber, comprising:
a first step of supplying the first process gas from a first gas supply passage to said process chamber; and
a second step of supplying the second process gas from a second gas supply passage to said process chamber and exciting plasma of the second process gas by plasma exciting means provided to said process chamber,
wherein, in the second step, a first reverse flow preventing gas consisting of H₂ or He is supplied to said process chamber from said first gas supply passage.

2. The film-forming method as claimed in claim 1, wherein the first step and the second step are repeated alternately for a plurality of times.

3. The film-forming method as claimed in claim 1, further comprising a step of purging said process chamber after each of the first step and the second step.

4. The film-forming method as claimed in claim 1, wherein, in the first step, a second reverse flow preventing gas is supplied to said process chamber from said second gas supply passage.

5. The film-forming method as claimed in claim 1, wherein the second process gas and the first reverse flow preventing gas are the same kind of gas.

6. The film-forming method as claimed in claim 1, wherein the second process gas is H₂.

7. The film-forming method as claimed in claim 1, wherein the first reverse flow preventing gas is H₂.

8. The film-forming method as claimed in claim 4, wherein the second reverse flow preventing gas is Ar.

9. The film-forming method as claimed in claim 1, wherein the metal is one of Ta, Ti and W.

10. The film-forming method as claimed in claim 1, wherein the first process gas is one of an amide compound gas, a halogen compound gas and a carbonyl compound gas.

11. The film-forming method as claimed in claim 10, wherein the amide compound gas is a gas selected from a group consisting of Ta(NC(CH₃)₂(C₂H₅)(N(CH₃)₂)₃, Ta[N(C₂H₅CH₃)]₅, Ta[N(CH₃)₂]₅, Ta(NC(CH₃)₃(N(C₂H₅)₂)₃, Ta(NC(CH₃)₃(N(CH₃)₂)₃, Ta(NC₂H₅)(N(C₂H₅)₂)₃, Ta(N(C₂H₅)₂(N(C₂H₅)₂)₃, Ti[N(C₂H₅CH₃)]₄, Ti[N(CH₃)₂]₄ and Ti[N (C₂H₅)₂]₄.

12. The film-forming method as claimed in claim 10, wherein the halogen compound gas is a gas selected from a group consisting of TaF₅, TaBr₅, TaI₅, TiCl₄, TiF₄, TiBr₄, TiI₄ and WF₆.

13. The film-forming method as claimed in claim 10, wherein the carbonyl compound gas is W(CO)₆.

14. The film-forming method as claimed in claim 1, wherein the first process gas and the second process gas are supplied to said process chamber through a shower head part provided in said process chamber.

15. The film-forming method as claimed in claim 14, wherein said plasma exciting means includes said shower head part to which a high-frequency power is applied to excite plasma.
